(19) United States
(12) Patent Application Publication
(10) Pub. No.: US 2015/0243854 A1
(43) Pub. Date: Aug. 27, 2015

(54) LIGHT-EMITTING APPARATUS, LED ILLUMINATION APPARATUS, AND METHOD FOR MANUFACTURING PHOSPHOR-CONTAINING FILM PIECE USED IN LIGHT-EMITTING APPARATUS

(71) Applicant: ELM Inc., Kagoshima (JP)

(72) Inventors: Tomio INOUE, Kagoshima (JP); Takakazu MIYAHARA, Kagoshima (JP)

(21) Appl. No.: 14/706,664

(22) Filed: May 7, 2015

Related U.S. Application Data
(63) Continuation of application No. PCT/JP2012/081944, filed on Dec. 10, 2012.

(51) Int. Cl. H01L 33/50

(52) U.S. Cl. CPC H01L 33/504; H01L 33/508; H01L 2933/0041

(57) ABSTRACT

Provided are: a lower-cost light-emitting apparatus with improved properties, as an LED device for illumination or an LED illumination apparatus such as an LED bulb, by eliminating interaction between phosphors and using a structure and mechanism design with optimized conditions; and a method for manufacturing the same. The present invention is a light-emitting apparatus including: a semiconductor light-emitting element that emits blue light, purple light or ultraviolet light; and a phosphor that is excited by light of the semiconductor light-emitting element to emit intrinsic light, wherein the apparatus has a specific structure, namely a phosphor separate-type structure, in which two or more kinds of phosphors of different luminous colors are used out of a blue phosphor for emitting blue light, a green phosphor for emitting green light, a yellow phosphor for emitting yellow light and a red phosphor for emitting red light as the intrinsic light, and the two or more kinds of phosphors are disposed in a lateral direction in such a state as not to vertically overlap with each other, to suppress interaction between the phosphors.

### BACKGROUND OF THE INVENTION

1. Field of the Invention

The present invention relates to a light-emitting apparatus used for LED illumination and the like, and particularly relates to a light-emitting apparatus, which is configured of a semiconductor light-emitting element for emitting blue light, purple light or ultraviolet light and a phosphor for converting the light to white light, an illumination apparatus and a method for manufacturing a phosphor-containing film piece used in the light-emitting apparatus.

2. Description of the Related Art

In recent years, an illumination apparatus using an LED has been put to practical use, and has been replacing an incandescent light bulb and a fluorescent lamp, and also a mercury lamp and a halogen lamp. This is because the illumination apparatus using the LED allows acquirement of brightness equivalent to that of the incandescent light bulb while consuming low electric power, and thus becomes a trump as an environmentally friendly product capable of significantly reducing carbon dioxide emissions which causes global warming. For example, the equivalent brightness to that of a 60 W incandescent light bulb can be realized by a 9 W LED bulb. As thus described, if every illumination is replaced by the LED illumination, reduction targets for carbon dioxide emissions would be easily achievable, but this has been prevented by still a large difference in price between the two kinds of illumination apparatuses. In view of the lifetime, the price difference therebetween has become quite small, and hence illumination in a specific location has been being replaced by the LED illumination due also to possible reduction in labor cost for the replacement.

The halogen lamp used for downlight and spot illumination of stores makes use of emission at the time of energizing a filament to get it incandescent in the same manner as the incandescent light bulb. Hence a color rendering index of the halogen lamp is high, the index being for evaluating color reproducibility, and a temperature of the filament of the halogen lamp can be made higher than that of a general incandescent light bulb, thereby allowing an increase in brightness by approximately 50%. Further, the lifetime is also extended. The reason for this is as follows. A material for the filament is tungsten. Tungsten sublimates as getting incandescent, and in a general incandescent light bulb, it is deposited on glass of the bulb. However, the halogen lamp repeats a halogen cycle: since a minute amount of a halogen gas is sealed in a bulb along with an inert gas, tungsten turns to halogenated tungsten, which is a material with high vapor pressure and is not precipitated as it is but separated into tungsten and halogen in the vicinity of the filament again, and tungsten returns to the filament.

The halogen lamp has a color temperature of approximately 2700 K to 3000 K and has the best color rendering properties among the lamps, and this light source is used in a location where the color reproducibility is important.

In the case of replacing the halogen lamp by the LED bulb, what are concerned are the brightness and the color rendering properties since the halogen lamp is used for illumination in the location where the color reproducibility is important, such as store illumination and stage illumination. As for the brightness, since a luminous efficacy of an LED element has been increased and an actual value of that of an LED device for illumination (LED electronic component for illumination) has reached 150 lm/W (5000 K) or 100 lm/W (3000 K), there seems to be no problem. Considering the color rendering properties, however, the luminous efficacy decreases. For example, in an LED device for illumination with a color temperature of 3000 K and an average color rendering index Ra of 80, the luminous efficacy can be 100 lm/W, but in an LED device for illumination with the same color temperature and Ra of 85, the luminous efficacy is as low as 80 lm/W. That is, when the color rendering properties are enhanced, the luminous efficacy decreases.

As a method for obtaining white light by use of a semiconductor light-emitting element (also referred to as LED element), YAG phosphor powder that emits, from blue light, light of yellow in a complementary relation with blue is used as a first step. However, pseudo white light made by the blue light of the LED element and the yellow light of the YAG phosphor has a value of the average color rendering index Ra as low as approximately 70, and it is thus unlikely that a natural color of a matter is reproduced with that illumination. The reason for Ra being low is that there are few red components of light.

Thus, as a second step, there has come to be used two kinds of phosphor powder that emit light of green and red as being among the three primary colors of light from the blue light of the LED element. The blue light of the LED element and the green light and red light having broad light spectrums from the two kinds of phosphors constitute white light. A value of its average color rendering index Ra is improved to 93, and the color reproducibility by the illumination is also considerably improved. However, the brightness as the white light decreases as described above. What causes this will be described later.

If the brightness of a semiconductor light-emitting element that emits purple light or ultraviolet light is enhanced in the future, as a third step, there will be used three kinds of phosphor powder which emit the three primary colors of light from purple light or ultraviolet light, and a value of Ra can be expected to become 100 which is equivalent to that of the halogen lamp.

The LED device for illumination used in the LED bulb is in the above second step at the current stage, and is configured of the LED element that emits blue light, the green phosphor that is excited by the blue light to emit broad green light, and the red phosphor that is excited by the blue light to emit broad red light. Since the brightness of light is also influenced by human visual sensitivity, it is represented by a luminous flux in view of the visual sensitivity, and lm (lumen) is used as its unit. The human visual sensitivity is the highest for yellow light with a wavelength of 555 nm, and is low for blue light and red light. For this reason, when the red light components made by the phosphor increase, the lumen value decreases. Improving the color rendering properties generally requires long-wave red light among red light, and the lumen value decreases accordingly.

In FIG. 7, a comparison of light spectrums is made between an LED device for illumination with a color temperature of about 3000 K and an average color rendering index Ra of 80 and an LED device for illumination with the same color temperature and Ra of not smaller than 90. In Sample 1 shown in FIG. 7, Ra is 96.4 and the brightness is 60.6 lm, and in Sample 2, Ra is 81.9 and the brightness is 70.1 lm. It is found that in the spectrum of Sample 1, the amount of the long-wave red light components is larger and the lumen value is accordingly lower than in the spectrum of Sample 2.

A first factor of the decrease in luminous flux value when the color rendering properties are improved is attributed to the above reason, but there is an important second factor other than that. This will be described below.

Generally, the green phosphor and the red phosphor are mixed at such a blending ratio as to allow reproduction of the color temperature. Also in the case of the LED device for illumination of FIG. 7, the phosphors are mixed and disposed around the LED element. In the case of mixing and using the green phosphor and the red phosphor in this manner, interaction has been generated between the phosphors. That is, while broad green light is emitted from the green phosphor excited by the blue light from the LED element, part of that light can also be light to excite the red phosphor.

FIG. 8 shows an example where such interaction is significant. Sample 3 of FIG. 8 is a spectrum in the case of mixing the green phosphor and the red phosphor in the same amount, and Sample 4 is one obtained by adding respective single spectrums of the green phosphor and the red phosphor (i.e., a spectrum in the case of there being no interaction between the two phosphors). Light characteristic values of the spectrum of Sample 3 are: luminous flux value=69.0 lm, Ra=69.0 and color temperature=2300 K. Light characteristic values of the spectrum of Sample 4 are: luminous flux value=72.2 lm, Ra=93.5 and color temperature=4096.9 K.

As seen from this emission spectrum data of Sample 3, when the phosphors are mixed in the same amount (i.e., when the mixing ratio of the green phosphor and the red phosphor is set to 1:1), no green light component appears and only the red light components increase. That is, green light has been reabsorbed by the red phosphor and converted to red light. As a result, the color temperature becomes 2300 K at which the color of the light is reddish, the color reproducibility deteriorates with Ra being as low as 69.0, and further, the luminous flux value decreases.

From this example, the following two points can be seen.

First, in Sample 3 in the case of mixing the phosphors, the light is subjected to two stages of conversion, which are conversion of blue light emitted by the LED element to broad green light by the green phosphor and further conversion of this green light to broad red light by the red phosphor, thereby involving a loss due to the two stages of conversion. That is, a loss has been generated in the luminous efficacy of white light as a total.

Secondly, the disappearance of the green light components leads to a great loss in average color rendering index Ra, not to mention a change in color temperature.

As thus described, the interaction between the phosphors has a deteriorating action on the luminous efficacy as well as on the color rendering properties. That is, it is found important to form a structure for eliminating the interaction between the phosphors in order to replace the light source with high color rendering properties and high brightness, such as the halogen lamp described above, by the LED bulb.

As one method for eliminating the interaction, a structural division may be made into a region for the green phosphor and a region for the red phosphor, and these may be disposed around the LED element. Such an example is shown in Japanese Patent No. 3978514 and Japanese Patent Laid-Open No. 2005-72129.

In the case of Japanese Patent No. 3978514, there are shown a structure where a green phosphor and a red phosphor are disposed in a divided manner on a blue LED element, and a structure where a blue phosphor, a green phosphor and a red phosphor are disposed in a divided manner on an ultraviolet LED element. Further, also in the case of Japanese Patent Laid-Open No. 2005-72129, there is shown a structure where a blue phosphor, a green phosphor and a red phosphor are disposed in a divided manner on an ultraviolet LED element.

However, no argument is made concerning interaction between different phosphors and the like in both of the documents. Japanese Patent No. 3978514 describes that adjusting an area of each emission sharing region, chromaticity of a phosphor layer or the like facilitates performing minute adjustment on an added and mixed color and bringing it close to ideal white light. Japanese Patent Laid-Open No. 2005-72129 describes that a quantity ratio of each phosphor can be controlled by an area ratio and hence variation in luminous color can be made smaller than in the case of mixing the phosphors. In each of the conventional documents, no argument is made concerning an effect on light characteristics by the interaction, and the like.

When the halogen lamp is to be reproduced by the LED device for illumination of the second step described above, it would be ideal that the reproduced one has a color temperature of not higher than 3000 K, color rendering properties with Ra of not smaller than 90, and a luminous efficacy of 100 lm/W. The LED device for illumination to date principally has a structure where a phosphor for reproducing a color temperature and color rendering properties is mixed with the LED element for emitting blue light and disposed on the light extraction surface of the LED element, and there do not exist an LED device for illumination and an LED bulb whose conditions are optimized in view of the interaction between the phosphors. For realizing the above ideal LED device for illumination, it is important to make a structure of the LED device for illumination or mechanistic design of the LED bulb which eliminates the interaction between the phosphors, while improving the luminous efficacy of the LED element and the conversion efficiency (efficiency in being excited by blue light to emit light of an intrinsic color) of the phosphor powder.

Further, even if a purple LED element and an ultraviolet LED element are improved in brightness and reduced in cost and a blue phosphor comes to be used as a phosphor in the future, it would be the same that the interaction among the blue phosphor, the green phosphor, the yellow phosphor and the red phosphor need to be considered even more.

The present invention was made in view of such actual situations as described above, and an object of the present invention is to provide in particular a lower cost light-emitting apparatus with improved properties, as an LED device for illumination or an LED illumination apparatus such as an LED bulb, by eliminating interaction between phosphors and using a structure and mechanism design with optimized conditions and a method for manufacturing the same.

### SUMMARY OF THE INVENTION

A light-emitting apparatus of a first aspect of the present invention comprises: a semiconductor light-emitting element that emits blue light, purple light or ultraviolet light; and a phosphor that is excited by light of the semiconductor light-emitting element to emit intrinsic light, wherein the apparatus has a specific structure, namely a phosphor separate-type structure, in which two or more kinds of phosphors of different luminous colors are used out of a blue phosphor for emitting blue light, a green phosphor for emitting green light, a yellow phosphor for emitting yellow light and a red phosphor for emitting red light as the intrinsic light, and the two or more kinds of phosphors are disposed in a lateral direction in such a state as not to vertically overlap with each other, to suppress interaction between the phosphors.

According to a second aspect of the present invention, a phosphor layer, which is configured of the phosphors constituting the phosphor separate-type structure, has a thickness of not larger than 500 μm.

As obvious from the emission spectrum data of Sample 3 shown in FIG. 8, when the green phosphor and the red phosphor are mixed just in the same mass and disposed on the light extraction surface of the LED element that emits blue light, interaction generated between the green phosphor and the red phosphor (i.e., green light having a broad spectrum and emitted from the green phosphor excited by blue light from the LED element is reabsorbed by the red phosphor to be converted to red light having a broad spectrum) is exerting an unfavorable critical effect on the luminous efficacy and the color rendering properties of white light as total light. That is, as described above, it becomes light subjected to two stages of conversion, which involves a loss due to the two stages of conversion, thereby leading to deterioration in luminous efficacy. Also, the disappearance of the green light components leads to a great loss in average color rendering index Ra, not to mention a change in color temperature.

As more specific data, FIG. 6 shows respective spectrums in the case of the same color temperature with the interaction between the green phosphor and the red phosphor generated (mixed-type sample/3B2D(7) 3:1) and in the case of the same color temperature without the interaction generated (separate-type sample/3B2D(2)(1)L7)). In the vicinity of the same color temperature of 3000 K, light characteristic values of the mixed type are: luminous flux=70.1 lm, Ra=81.9 and R9=5.3, and light characteristic values of the separate type are: luminous flux=73.8 lm, Ra=85.2 and R9=25.4. It is found from these data that the separate-type sample without the interaction has a better luminous efficacy and color rendering properties as white light.

Another phosphor has similar interaction with the red phosphor, and in particular, the blue phosphor also has interaction with the green phosphor or the yellow phosphor.

As thus described, forming a specific structure where the interaction between the phosphors is suppressed can realize illumination with favorable color rendering properties and high brightness. Here, the specific structure specifically means a phosphor separate-type structure, and in the structure where phosphors of different luminous colors are not mixed but separated, a thickness of a boundary is preferably set to not larger than 500 μm (more preferably not larger than 300 μm) so that the interaction on the separated boundary surface can be made minute.

According to a third aspect of the present invention, the light-emitting apparatus is configured such that light is emitted by the semiconductor light-emitting element for emitting blue light, purple light or ultraviolet light and the phosphor layer formed on a light extraction surface of the semiconductor light-emitting element, and the phosphor layer is configured by being divided into a plurality of regions vertically to a layer surface so that any one phosphor of the blue phosphor, the green phosphor, the red phosphor and the yellow phosphor is allocated to each of the divided regions and so that a percentage of a gross area of the red phosphor to a total area of the phosphor layer becomes the largest, to constitute the specific structure.

Realizing a halogen lamp by an LED device requires an LED device with favorable color rendering properties and high brightness. For such a purpose, it is of necessity to form a structure where there hardly is interaction between a plurality of phosphors which are used for the phosphor layer. As one method for this, the phosphor layer is divided into a plurality of regions by a plane vertical to the layer surface, any one phosphor of the blue phosphor, the green phosphor, the red phosphor and the yellow phosphor is allocated to each of the divided regions to constitute the phosphor layer, thereby allowing elimination of most of interaction between the phosphors.

Further, the color temperature of the halogen lamp is not higher than 3000 K, and for setting to such a color temperature, the area of the divided region for the red phosphor needs to be larger than the area of the divided region for any other phosphor.

A specific description will be given by means of the samples with a color temperature of 3000 K in FIG. 6. In the case of the mixed-type sample with the interaction generated between the phosphors, a weight ratio of the green phosphor and the red phosphor is 3:1 and the weight of the green phosphor needs to be made three times as large as the weight of the red phosphor. However, in the case of the separate-type sample with the interaction hardly generated, the weight ratio is 1:1.66 and the weight of the red phosphor is larger. Further, as for an area ratio of the divided regions of the phosphor layer, a ratio of the area of the divided region for the green phosphor and the area of the divided region for the red phosphor is 7:17, and the area of the divided region for the red phosphor is taken more than 2.4 times larger. As thus described, in the structure with the interaction between the phosphors eliminated, in order to obtain a light source of the color of the halogen lamp or the bulb, it is important to make the area of the divided region for the red phosphor larger than the area of the divided region for any other phosphor.

According to a fourth aspect of the present invention, the red phosphor contains a phosphor of a different luminous color for adjusting spectral characteristics.

As shown in FIG. 8, even when the red phosphor is mixed with the same amount of the green phosphor, a luminous color from the mixed phosphor becomes a red color, but the shape of its spectrum is different from that in the case of using a single red phosphor in terms of a peak value and a tail shape. This is natural, for green light converted (by the green phosphor) from blue light from the LED element is not all converted to red, and non-converted light changes the shape of the tail. There are cases where this is more favorable in the viewpoint of the color rendering properties or of the manufacturing method despite generation of a slight loss due to the double conversion. In those cases, the above mixture may be used. That is, the red phosphor may be mixed with a phosphor of a different luminous color for adjusting the spectral shape.

This is not restricted to the red phosphor, but also applies to the blue phosphor, the green phosphor and the yellow phosphor. A phosphor which is mixed with a phosphor of a different luminous color to such an extent as to adjust a peak value and a tail shape of a spectrum within the range of a color zone of intrinsic light of the phosphor to serve as a base also belongs to the phosphor for emitting the intrinsic light of the phosphor to serve as the base.

According to a fifth aspect of the present invention, the light-emitting apparatus is configured such that light is emitted by the semiconductor light-emitting element for emitting blue light, purple light or ultraviolet light and the phosphor layer formed on the light extraction surface of the semiconductor light-emitting element, and an increasing rate of an emission intensity component value S2 of an emission spectrum of the light-emitting apparatus at a wavelength of 530 nm to an emission intensity component value S1 of the emission spectrum at a wavelength of 520 nm, namely (S2−S1)/S1, is a negative value or a positive value and not higher than 6%.

A portion characteristically different between the mixed-type sample and the separate-type sample of FIG. 6 is a portion of a spectrum of green light. While it has been repeatedly described that this is a difference due to the generation or non-generation of the interaction between the phosphors, this shows that, when the increasing rate of the emission intensity component value S2 of the emission spectrum at a wavelength of 530 nm to the emission intensity component value S1 of the emission spectrum at a wavelength of 520 nm, namely (S2−S1)/S1, satisfies a negative value or a positive value being not higher than 6% at an arbitrary color temperature (especially the range from 3000 K to 6000 K), an LED device for illumination with favorable color rendering properties and high brightness can be obtained.

According to a sixth aspect of the present invention, the light-emitting apparatus is configured by superimposing and disposing, on the semiconductor light-emitting element which emits blue light, purple light or ultraviolet light, has two opposing principal surfaces, and takes the one principal surface as a light extraction surface and the other principal surface as an electrode formation surface, a phosphor-containing film piece which has two opposing principal surfaces equivalent to or larger than the light extraction surface and takes the one principal surface as a light entrance surface and the other principal surface as a light exit surface, such that the light extraction surface and the light entrance surface are opposed to each other, and the phosphor-containing film piece is configured by being divided into a plurality of regions vertically to the principal surface so that any one phosphor of the blue phosphor, the green phosphor, the red phosphor and the yellow phosphor is allocated to each of the divided regions, to constitute the specific structure.

In order to realize a single LED device for illumination as a structure that eliminates most of the interaction between the phosphors, a structure formed with a phosphor film piece is most practical. For example, one obtained by mixing red phosphor powder into a silicon resin to make a paste, is printed on a plastic sheet by screen printing and cured, to form a film-shaped phosphor-containing film piece. Subsequently, a plurality of lines of grooves having a blade width are formed by use of a dicer, and part of the phosphor-containing film piece is ground to remove the phosphor. Thereafter, one obtained by mixing green phosphor powder into a silicon resin to make a paste, is applied onto the portion subjected to the removal of the red phosphor, and then cured. In such a manner, there is produced a phosphor-containing film piece formed by separating the region for the red phosphor and the region for the green phosphor. When this is disposed on the light extraction surface of the semiconductor light-emitting element (LED element), a light-emitting apparatus with interaction hardly generated between the red phosphor and the green phosphor is produced. In order to add regions for the blue phosphor and the yellow phosphor, the above method may be repeated.

According to a seventh aspect of the present invention, the number of regions of the phosphor-containing film piece is set to one, and any one kind of the blue phosphor, the green phosphor, the red phosphor and the yellow phosphor is allocated to the region.

When the phosphor-containing film piece is not divided and any one kind of the blue phosphor, the green phosphor, the red phosphor and the yellow phosphor is used for this, interaction between the phosphors is naturally not generated. When a plurality of such light-emitting apparatuses for emitting blue, green, red and yellow light are used to produce an LED bulb for emitting white light as a total, it becomes an illumination apparatus with the interaction between the phosphors suppressed.

According to an eighth aspect of the present invention, interaction between phosphors is suppressed by use of the light-emitting apparatus in an LED illumination apparatus.

When the light-emitting apparatus according to the sixth aspect of the present invention or a plurality of light-emitting apparatuses according to the seventh aspect of the present invention are used to produce an LED bulb, a linear light source or a planar light source for emitting white light as a total, it can be used as a bulb-shaped, linear or planar LED illumination apparatus with the interaction between the phosphors suppressed.

According to a ninth aspect of the present invention, an method for manufacturing a phosphor-containing film piece comprises: a step 1 of mixing a resin and first phosphor powder of any of a blue phosphor, a green phosphor, a red phosphor and a yellow phosphor to make a paste, applying the paste in a film form onto a heat resistant plastic sheet, and curing the paste to form a first phosphor-containing film piece; a step 2 of removing the first phosphor-containing film from a portion region for the first phosphor-containing film piece (a portion corresponding to the divided region); and a step 3 of applying a paste, obtained by mixing a resin and second phosphor powder of any of the blue phosphor, the green phosphor, the red phosphor and the yellow phosphor to make a paste, into the portion region and curing the paste to form a second phosphor-containing film divided region.

Specifically, for example, the method of the step 1 for forming a paste by use of a transparent silicon resin as the resin to be mixed with the phosphor powder to apply the paste is performed by screen printing using a metal mask. Further, as the method of the step 2 for removing the first phosphor-containing film from the portion region for the first phosphor-containing film piece, there may be used a method for shaving off the film just by a target width with the dicer by use of a dicing blade having a thickness of 200 μm, for example. Moreover, the method of the step 3 for applying the second phosphor-containing paste into the portion region subjected to the removal is performed using a dispenser, and finally, the surface is leveled so as to be flat, and then cured, thereby allowing the separate-type phosphor-containing film piece to be manufactured.

According to a tenth aspect of the present invention, steps corresponding to the step 2 and the step 3 are repeated a plurality of times, to form a plurality of phosphor-containing film divided regions.

In order to make optical characteristics (luminous flux value, color temperature, color rendering properties) favorable, a plurality of above divided regions need to be formed. However, repeating the step 2 and the step 3 with different kinds of phosphors makes it possible to form a separate-type phosphor-containing film piece having a plurality of divided regions, so as to produce a light-emitting apparatus with the interaction between the phosphors suppressed.

In addition, even when phosphors, materials for which are different and which emit light of the same color, are mixed with each other, interaction between the phosphors is not generated, and hence that mixed phosphor may be used in the divided region.

The light-emitting apparatus of the present invention has the structure where the interaction between the phosphors used in the illumination apparatus is suppressed. The case of the green phosphor and the red phosphor will be described as an example. Firstly, in the conventional mixed phosphor, intersection exists in two stages of conversions: first conversion from blue light emitted by the LED element to broad green light by the green phosphor; and further conversion of this light to broad red light by the red phosphor, and a loss is involved due to the two stages of conversion. However, in the present invention, this loss can be eliminated.

Secondly, in the conventional mixed phosphor, the green light components disappear due to the interaction, thus leading to a great loss in average color rendering index Ra, not to mention a change in color temperature. However, in the present invention, this loss can also be eliminated.

As thus described, the interaction between the phosphors has a deteriorating action on the luminous efficacy as well as on the color rendering properties, but the present invention makes it possible to greatly reduce those losses and produce an LED illumination apparatus such as an LED bulb with high brightness and high color rendering by suppressing the interaction.

### BRIEF DESCRIPTION OF THE DRAWINGS

FIGS. 1A to 1C are views of a light-emitting apparatus of a first embodiment of the present invention, where FIG. 1A is a plan view seen from top, FIG. 1B is a plan view seen from below, and FIG. 1C is a sectional view along a line A-A;

FIGS. 2A to 2C are views of a light-emitting apparatus of a second embodiment of the present invention, where FIG. 2A is a plan view seen from top, FIG. 2B is a plan view seen from below, and FIG. 2C is a sectional view along a line B-B;

FIGS. 3A to 3C are views of a phosphor-containing film piece used in the light-emitting apparatus of the present invention;

FIG. 4 is a plan view of a light-emitting apparatus of a fifth embodiment of the present invention;

FIGS. 5A to 5D are views showing a method for manufacturing a separate-type phosphor-containing film piece of the present invention;

FIG. 6 is emission spectrum data No1 of the light-emitting apparatus;

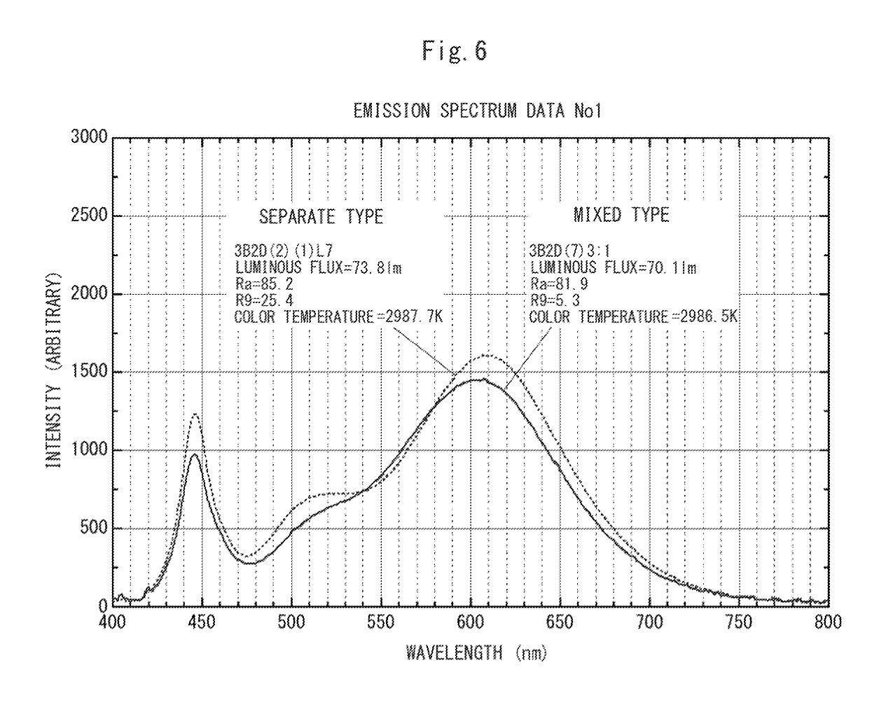

FIG. 7 is emission spectrum data No2 of the light-emitting apparatus;

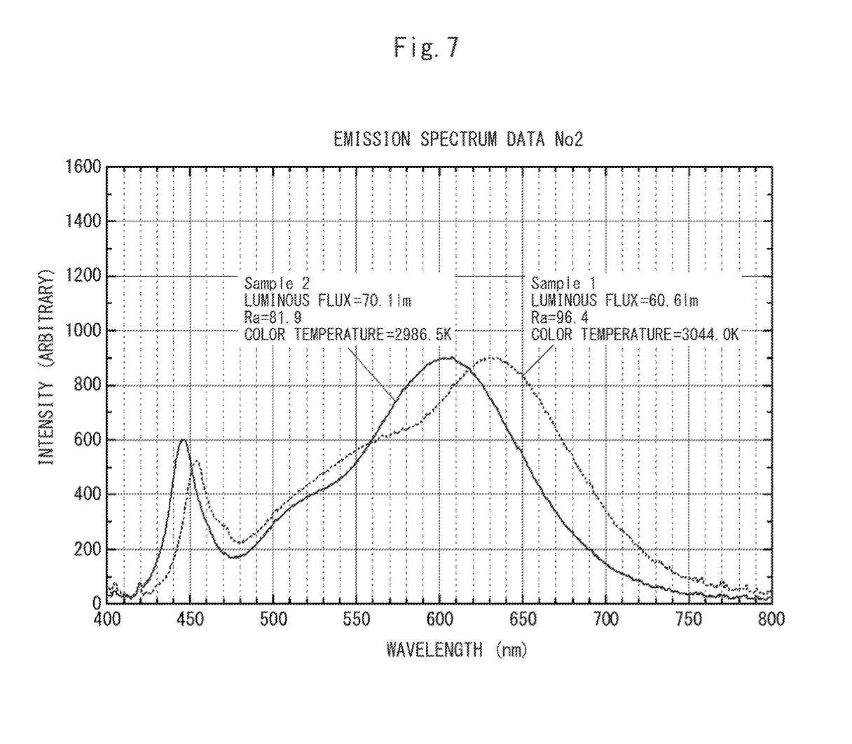

FIG. 8 is emission spectrum data No3 of the light-emitting apparatus;

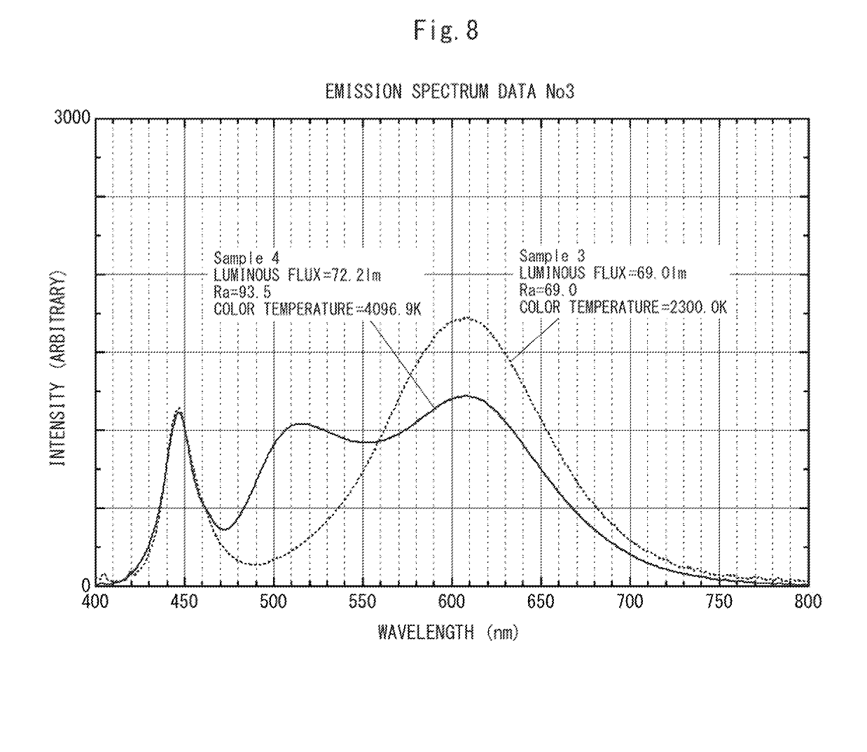

FIG. 9 is emission spectrum data No4 of the light-emitting apparatus; and

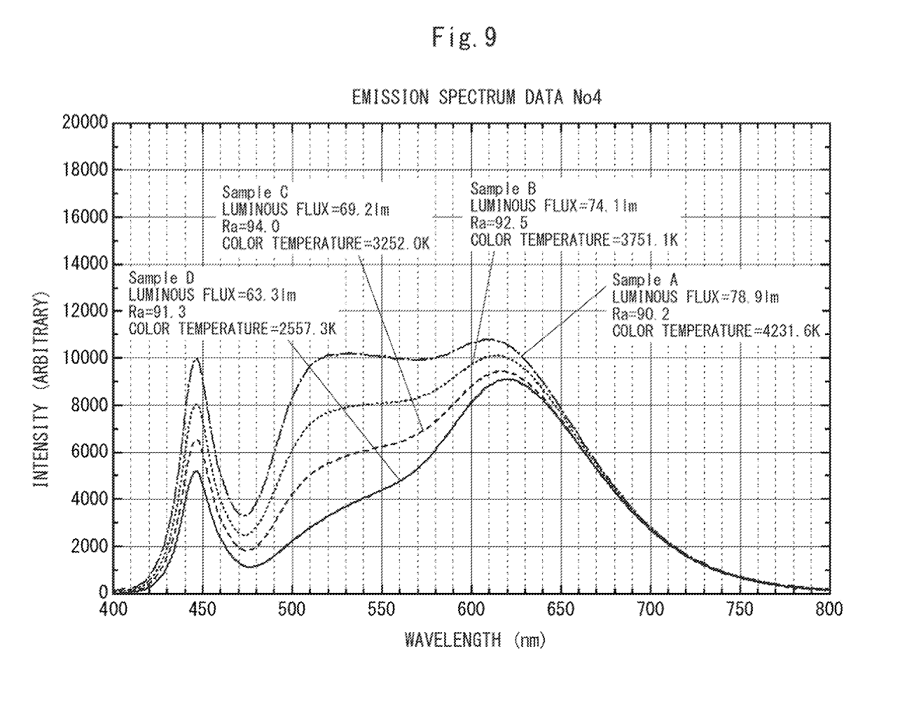

FIG. 10 is emission spectrum data No5 of the light-emitting apparatus.

### DETAILED DESCRIPTION OF THE PREFERRED EMBODIMENTS

Hereinafter, embodiments of the light-emitting apparatus of the present invention will be described in detail in the order of first to third embodiments with respect to the drawings.

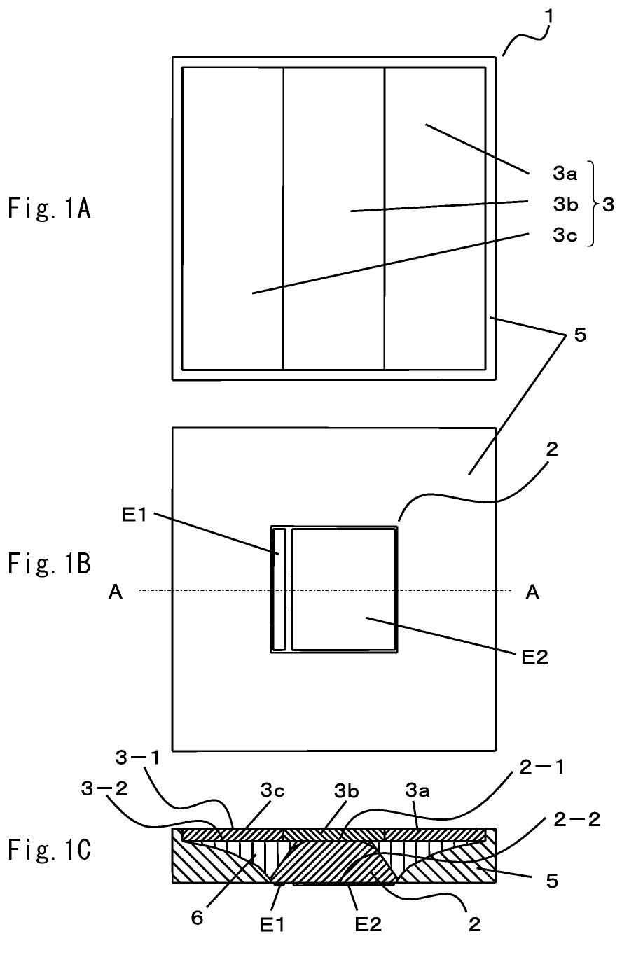

First, FIGS. 1A to 1C show a light-emitting apparatus of the first embodiment.

This light-emitting apparatus 1 includes an LED element 2, a separate-type phosphor-containing film piece 3, a reflection wall 5, and a transparent resin section 6. The LED element 2 emits blue light and has a trapezoidal shape with a light extraction surface 2-1 being smaller than an electrode formation surface 2-2. The side surface of the LED element 2 is inclined, and taking light also from this surface has been considered. AuSn layers with a thickness of 3 μm are formed on surface layers of an n-side electrode and a p-side electrode of the electrode formation surface 2-2 of the LED element 2, and those are taken as a + electrode E1 and a − electrode E2. On the light extraction surface 2-1 of the LED element 2, the separate-type phosphor-containing film piece 3 including phosphor powder (i.e., regions 3a, 3c containing red phosphor powder and a region 3b containing green phosphor powder) is disposed as a phosphor separate-type structure. On the side surface of the LED element 2, the transparent resin section 6 is formed which has a reversed quadrangular pyramid shape with the separate-type phosphor-containing film piece 3 taken as its bottom. Further, the reflection wall 5 covers the exposed surface except for the whole surface of the electrode formation surface 2-2, or the + electrode El section and the − electrode E2 section of the electrode formation surface 2-2, of the LED element 2 and a light exit surface 3-1 of the separate-type phosphor-containing film piece 3 that emits total white light.

This light-emitting apparatus 1 does not have what corresponds to a substrate in a conventional structure, and the electrodes of the LED element 2 (the + electrode E1 and the − electrode E2 whose surfaces are formed with the AuSn layers having a thickness of 3 μm) are mounted directly on a mounting substrate by soldering. This can hold thermal resistance as a device small and eliminates the need for material cost of an expensive substrate, thus allowing a low price to be realized.

Further, the brightness (luminous flux: lumen value) of the light-emitting apparatus 1 with this structure depends greatly on a size (breadth) of the separate-type phosphor-containing film piece 3. For example, in the case of a 3 W LED element 2, when the size of the separate-type phosphor-containing film piece 3 is a square with a side of 2.4 mm to 3.0 mm, the light extraction efficiency becomes the highest, and the brightness becomes the highest (the lumen value becomes the largest). When the size is not larger than that, the light extraction efficiency becomes lower, and the brightness becomes lower (the lumen value becomes smaller).

The LED element 2 is one obtained by stacking a GaN-based compound semiconductor film on the surface of a transparent crystal substrate (e.g., sapphire substrate, SiC substrate, GaN substrate, etc.) in the order of a buffer layer, an n-type layer, an emission layer for emitting blue light and a p-type layer from the substrate side, forming a p-side electrode on the surface of a p-type layer and forming an n-side electrode on a portion where the p-type layer and the light-emitting layer are partially selectively etched to expose the n-type layer. The p-side electrode and the n-side electrode are formed on almost the same plane. The AuSn layer with a thickness of 3 μm is formed on each surface of these electrodes.

The separate-type phosphor-containing film piece 3 is divided into three regions as the phosphor layer. The regions 3a, 3c are regions formed by mixing the red phosphor powder into, for example, resin-type silicone, applying the mixture in a film form and curing it, and the region 3b is a region formed by curing the green phosphor in the same manner as above. Although a specific method for manufacturing those will be described later, a red phosphor-containing film is formed by screen printing using a metal mask. A part (divided region) of the film is ground and removed by use of a dicer or the like, and a green phosphor-containing film is formed in the divided region subjected to the removal by use of a dispenser or the like.

Here, the green phosphor is, for example, CaSc₂O₄:Ce, and it may be one kind of green phosphor or may be one obtained by mixing two or more kinds of green phosphors. Further, the red phosphor is, for example, (SrCa)AlSiN₃:Eu, and it may be one kind of phosphor or may be one obtained by mixing two or more kinds of red phosphors. As for a blended amount, for example in the apparatus with a color temperature of about 3000 K, in the case of the red phosphor-containing film in the divided regions 3a, 3c, a weight concentration of the phosphor powder is 37.0% and a percentage of its area to the whole area is 70.8%, and in the case of the green phosphor-containing film in the divided region 3b, a weight concentration of the phosphor powder is 54.1% and a percentage of its area to the whole area is 29.2%. While the color temperature can be adjusted by changing the weight ratio or by changing the area, conditions for favorable color rendering properties and a large luminous flux value are selected. Also in this case, the divided region for the red phosphor-containing film becomes the broadest.

Since the length of the boundary surface between the divided regions 3a, 3c for the red phosphor and the divided region 3b for the green phosphor becomes approximately 2.4 mm to 3.0 mm, in order to minimize interaction on the boundary surface, the thickness of the separate-type phosphor-containing film piece 3 (thickness of the phosphor layer) is set to approximately 100 μm.

The width of the divided region 3b for the green phosphor may become approximately 500 μm, which requires the thickness of the phosphor layer to be set to not larger than 500 μm. It is preferably set to not larger than 300 μm. When it exceeds 500 μm, the interaction becomes large, which is inappropriate.

As for resin-type silicone, there is used one having a high refractive index (1.5 to 1.55), a hardness of Shore D (40 to 70, preferably 60 to 70), and a favorable transparency (e.g., a light permeability of not less than 95%, preferably not less than 99%, with respect to blue light with a wavelength of 450 nm in the case of the resin having a thickness of 1 mm).

The transparent resin section 6 having the reversed quadrangular pyramid shape serves as a light propagation layer for efficiently letting blue light, taken from the inclined surface of the LED element 2, into the separate-type phosphor-containing film piece 3 located on the top surface of the LED element 2. Therefore, for example, resin-type silicone having a high refractive index (1.5 to 1.55), a hardness of Shore D (approximately 40 to 70), and a favorable transparency (e.g., a light permeability of not less than 95%, preferably not less than 99%, with respect to blue light with a wavelength of 450 nm in the case of the resin having a thickness of 1 mm) is also used for this portion.

The LED element 2 and the separate-type phosphor-containing film piece 3 are bonded to each other by use of the same resin-type silicone as the one for the transparent resin section 6. This silicon resin may be mixed with an appropriate amount of the above phosphor for correcting a chromaticity or a color temperature.

The reflection wall 5 is one formed by mixing titanium oxide fine powder having a particle diameter of 0.21 μm with, for example, resin-type silicone and curing the mixture. Titanium oxide has a large dielectric constant and a high light reflectivity, and is thus often used for a reflection wall. However, since titanium oxide has photocatalytic properties, it is exited more by ultraviolet light or blue light and acts on surrounding moisture and oxygen to make an O₂H radical or an OH radical, causing degradation and discoloring of the silicon resin. For this reason, a reflection wall (white) around the blue LED element is discolored, and its brightness is degraded to not higher than 80% in tens of hours. Accordingly, titanium oxide fine particles to be used here is one prevented from having the photocatalytic properties by coating of the surfaces thereof with silica or alumina or by treatment with siloxane. Further, it is also necessary to set a blending ratio thereof to the silicon resin to approximately 5% to 30% in terms of pigment volume concentration, so as to prevent a decrease in reflectivity due to a dense effect.

Moreover, as for resin-type silicone, there is used one having a high refractive index (1.5 to 1.55), a hardness of Shore D (50 to 70, preferably 60 to 70), and a favorable transparency (e.g., a light permeability of not less than 95%, preferably not less than 99%, with respect to blue light with a wavelength of 450 nm in the case of the resin having a thickness of 1 mm). The thickness of the side surface of the phosphor-containing film piece 3 is approximately 60 μm. The side surface of the LED element 2 is formed to be inclined outwardly from the separate-type phosphor-containing film piece 3 to the electrode formation surface 2-2. Accordingly, a reflection wall is formed on the side surface side of the LED element 2 so to allow a large amount of light to travel toward the separate-type phosphor-containing film piece 3.

From a result of the consideration made so far by use of the light-emitting apparatus 1 of the present example, when the separate-type phosphor-containing film piece 3 is configured using, as phosphors to be used for the separate-type phosphor-containing film piece 3, red phosphors of (SrCa)AlSiN₃:Eu (this is referred to as 2D phosphor) and CaAlSi(ON)₃:Eu (this is referred to as 3A phosphor), a green phosphor of CaSc₂O₄:Ce (this is referred to as 3B phosphor) and a yellow phosphor of a general formula: M₁₋ₐSi₂O_{2-1/2n}XₙN₂:Euₐ (this is referred to as 3S phosphor), the sample film piece 3 has an average color rendering index Ra of not lower than 90 with the color temperature in the range of 2500 K to 4200 K, whose constitutional contents will be described below.

TABLE 1

| | Sample A | | Sample B | | Sample C | | Sample D | |
|---|---|---|---|---|---|---|---|---|
| | Phosphor | Area | Phosphor | Area | Phosphor | Area | Phosphor | Area |
| Phosphor | concentration | percentage | concentration | percentage | concentration | percentage | concentration | percentage |
| 2D | 54.1% | 22.2% | 54.1% | 25.0% | 54.1% | 28.6% | 54.1% | 33.3% |
| 3A | 54.1% | 22.2% | 54.1% | 25.0% | 54.1% | 28.6% | 54.1% | 33.3% |
| 3B | 54.1% | 44.4% | 54.1% | 37.5% | 54.1% | 28.6% | 54.1% | 16.7% |
| 3S | 54.1% | 11.1% | 54.1% | 12.5% | 54.1% | 14.3% | 54.1% | 16.7% |

| | | | | |
|---|---|---|---|---|
| Color temperature | 4231.6 K | 3751.1 K | 3252.0 K | 2557.3 K |
| Ra | 90.2 | 92.5 | 94.0 | 91.3 |
| Luminous flux | 78.9 lm | 74.1 lm | 69.2 lm | 63.3 lm |
| Increasing rate | 0.6% | 2.7% | 5.2% | 12.3% |

The increasing rate here means the increasing rate of the emission intensity component value S2 of the emission spectrum at a wavelength of 530 nm to the emission intensity component value S1 of the emission spectrum at a wavelength of 520 nm, namely (S2−S1)/S1.

It is found from this result that with the color temperature of not higher than 4000 K, an area percentage (sum of area percentages of 2D and 3A) of the red phosphor is larger than an area percentage of any other phosphor. Further, it is found that with the color temperature being not lower than 3000 K, the increasing rate is not higher than 6%.

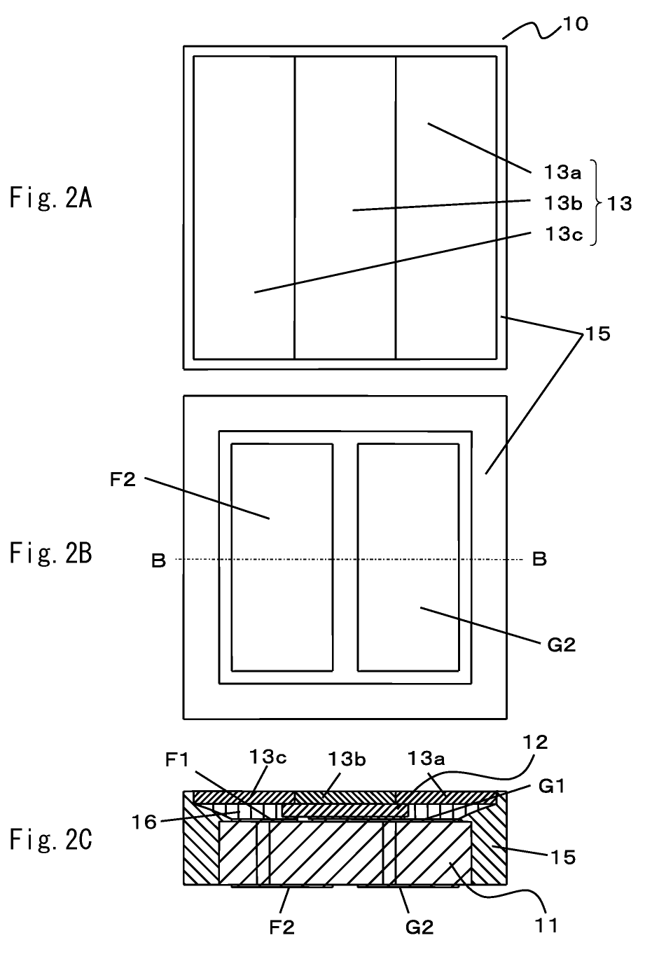

Next, FIGS. 2A to 2C show a light-emitting apparatus of the second embodiment.

This light-emitting apparatus 10 is formed in a double structure by mounting a 3 W LED element 12 of a flip chip type, which emits blue light and extracts light from the surface (light extraction surface) on the opposite side to the electrode formation surface formed with an n-side electrode (− electrode) and a p-side electrode (+ electrode), on chip mounting electrodes (F1, G1) of a ceramic, aluminum oxide substrate (or aluminum nitride substrate) 11 via an Au stud bump (bump made by use of Au wires). In view of heat dissipation, the thickness of this substrate 11 is set to about 0.5 mm, and (also in view of cost,) the size thereof is set to a square with a side of about 2 mm and slightly larger than the LED chip. Through holes electrically connect between F1 of chip mounting electrodes (F1, G1) formed on the substrate of the double structure and F2 of external substrate mounting electrodes (F2, G2), and also connect between G1 of the chip mounting electrodes (F1, G1) and G2 of the external substrate mounting electrodes (F2, G2).

The light entrance surface of a separate-type phosphor-containing film piece 13, which is the same as the one described in the first embodiment, is bonded onto the top surface (light extraction surface) of the LED element 12 of the double structure by a silicon resin. The separate-type phosphor-containing film piece 13 has a thickness of about 0.1 mm, and a size of a square with a side of about 2.4 mm.

The side surface of the LED element 12 is formed with a transparent resin section 16, which is made of a silicon resin, having a reversed quadrangular pyramid shape with the separate-type phosphor-containing film piece 13 taken as its bottom.

Further, the exposed surface except for the formation surface of the external substrate mounting electrode (F2, G2) of the substrate 11 of the double structure and the light exit surface of the separate-type phosphor-containing film piece 13 is covered with a white resin obtained by mixing the titanium oxide fine powder into a silicon resin to form a reflection wall 15, to produce the light-emitting apparatus 10.

This structure has the shape of the substrate 11 being embedded in the white resin, and is different from the conventional one in which all the resin structure is formed on the substrate. The substrate 11 is formed to have the minimum size required for being mounted with the LED element 12 and dissipating heat generated in the LED element 12, and hence it is possible to save material cost of an expensive substrate.

Further, the brightness (luminous flux: lumen value) of the light-emitting apparatus 10 with this structure depends greatly on the size (breadth) of the separate-type phosphor-containing film piece 13. For example, in the case of a 3 W LED element 12, when the size of the separate-type phosphor-containing film piece 13 is a square with a side of 2.4 mm to 3.0 mm, the light extraction efficiency becomes the highest, and the brightness becomes the highest (the lumen value becomes the largest). When the size is not larger than that, the light extraction efficiency becomes lower, and the brightness becomes lower (the lumen value becomes smaller). That is, the separate-type phosphor-containing film piece 13 needs to be made larger than the substrate.

Moreover, the thickness of the separate-type phosphor-containing film piece 13 is set to approximately 100 μm as the phosphor separate-type structure for making small the interaction on the boundary surface of the phosphor divided regions.

The LED element 12 is one obtained by stacking a GaN-based compound semiconductor film on the surface of a transparent crystal substrate (e.g., sapphire substrate, SiC substrate, GaN substrate, etc.) in the order of a buffer layer, an n-type layer, an emission layer for emitting blue light and a p-type layer from the substrate side, forming a p-side electrode on the surface of a p-type layer and forming an n-side electrode on a portion where the p-type layer and the light-emitting layer are partially selectively etched to expose the n-type layer. The p-side electrode and the n-side electrode are formed on almost the same plane, although there is a step of several μm. An Au layer is formed on each surface of these electrodes.

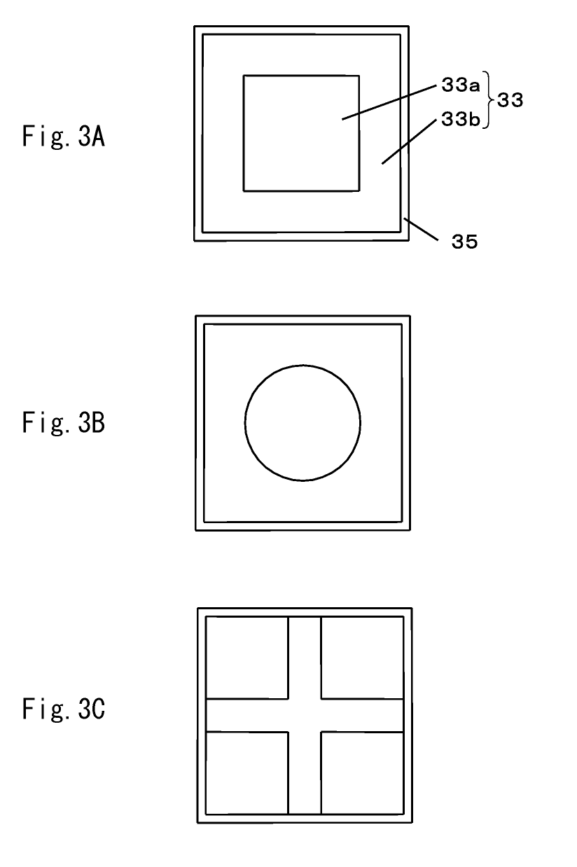

The separate-type phosphor-containing film piece 13 is the same as that in the first embodiment. Further, as shown in FIGS. 3A to 3C, the divided region may be formed in a variety of shapes such as a square, a circle and a cross shape. Moreover, these shapes may be reduced in size and a plurality of them may be formed. However, when the size of the divided region becomes small, the interaction on the boundary surface thereof exerts a large effect, thus requiring the thickness of the separate-type phosphor-containing film piece 13 to be small.

Next, a light-emitting apparatus of a third embodiment is a light-emitting apparatus where the number of divided regions of the separate-type phosphor-containing film 3 of the light-emitting apparatus 1 of the first embodiment is set to one, namely, one kind of phosphor out of the blue phosphor, the green phosphor, the red phosphor and the yellow phosphor is used for the whole of the phosphor-containing film piece. A tone of light is mixed by intrinsic light of one kind of phosphor and blue light of the LED element. In the case of using the yellow phosphor, initial pseudo white is obtained, but when the concentration of the phosphor is increased, light has a color intrinsic to the phosphor.

Further, a light-emitting apparatus of a fourth embodiment is a light-emitting apparatus obtained by using the phosphor-containing film piece, described in the third embodiment, in the light-emitting apparatus 10 of the second embodiment.

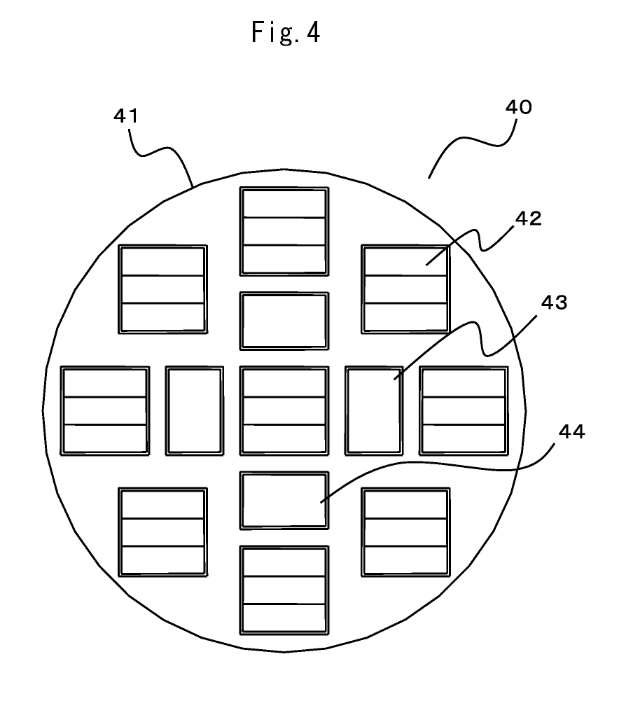

Next, FIG. 4 shows a light-emitting apparatus of a fifth embodiment. This light-emitting apparatus 40 is designed so as to hold a light source within a circle 41 having a diameter of 12.5 mm, and the inside thereof is configured of: nine light-emitting apparatuses 42 each being the light-emitting apparatus of the first embodiment and having a size of a square with a side of about 2.6 mm and a height of about 0.5 mm; two light-emitting apparatuses 43 each being the light-emitting apparatus of the third embodiment, having a size of a rectangle of about 2.6×1.8 mm and a height of about 0.5 mm and containing the red phosphor as a phosphor-containing film piece; and two light-emitting apparatuses 44 of the third embodiment, having a size of a rectangle of about 2.6×1.8 mm and a height of about 0.5 mm and containing the green phosphor as a phosphor-containing film piece.

With the configuration of this light-emitting apparatus 40, it is possible to greatly suppress the interaction between the phosphors also as the whole of the light-emitting apparatus, so as to design an LED bulb with high color rending and high brightness.

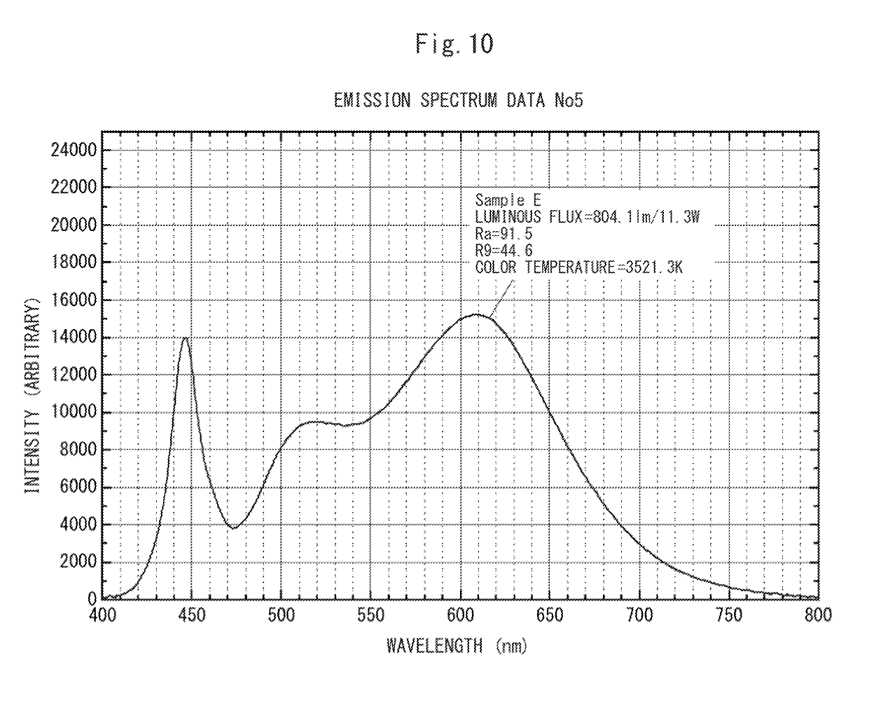

The light characteristics of the light-emitting apparatus 40 are: a luminous flux value=804.1 lm/11.3 W, Ra=91.5, R9=44.6 and color temperature=3521.3 K. Further, FIG. 10 shows a light spectrum.

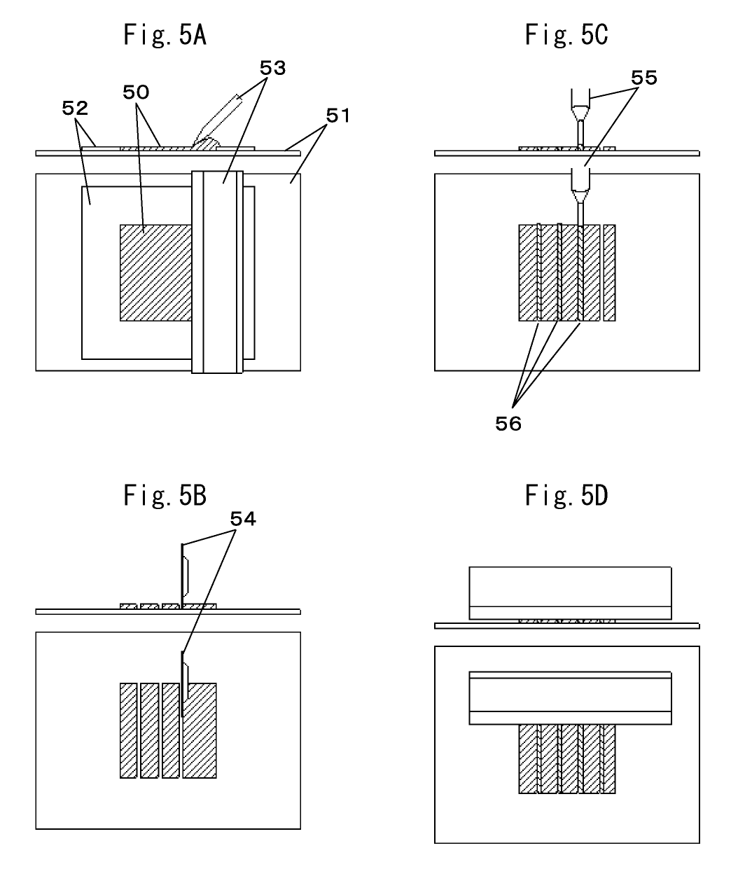

Next, as a sixth embodiment, a method for manufacturing the separate-type phosphor-containing film piece 3 will be described in accordance with FIGS. 5A to 5D.

First, a red phosphor is taken as a first phosphor, and mixed in an appropriate amount with a silicon resin, to prepare a first phosphor-containing resin paste, and a green phosphor is taken as a second phosphor, and mixed in an appropriate amount with a silicon resin, to prepare a second phosphor-containing resin paste.

Next, as shown in FIG. 5A, a first phosphor-containing resin paste 50 is applied onto a heat resistant plastic sheet (e.g., PET sheet) 51 by screen printing using a metal mask 52 so as to form a uniform film form by means of a squeegee 53, which is then cured in a curing oven on conditions of 150° C. and one hour, to prepare a first phosphor-containing film piece (step 1).

Next, as shown in FIG. 5B, by use of a dicing blade 54 with a blade width of about 200 μm, the first phosphor-containing film is removed in a stripe form just by an appropriate amount of width (a portion corresponding to the divided region) by the dicer (step 2).

Next, as shown in FIG. 5C, a second phosphor-containing resin paste is applied into the stripe-like portion subjected to the removal (the portion corresponding to the divided region) by use of, for example, a dispenser 55, which is then cured in the curing oven on conditions of 150° C. and one hour, to form a second phosphor-containing film divided region 56 (step 3). In this case, after application of the second phosphor-containing resin paste by the dispenser 55, as shown in FIG. 5D, the surface may be leveled using the squeegee 53 so as to be flat, and then cured.

By the above manufacturing method, it is possible to manufacture a uniform separate-type phosphor film piece.

Moreover, repeating the above step 2 and step 3 for a third phosphor and a fourth phosphor allows formation of a plurality of phosphor-containing film divided regions.

What is claimed is:

1. A light-emitting apparatus comprising:
a semiconductor light-emitting element that emits blue light, purple light or ultraviolet light; and
a phosphor that is excited by light of the semiconductor light-emitting element to emit intrinsic light,
wherein the apparatus has a specific structure, namely a phosphor separate-type structure, in which
two or more kinds of phosphors of different luminous colors are used out of a blue phosphor for emitting blue light, a green phosphor for emitting green light, a yellow phosphor for emitting yellow light and a red phosphor for emitting red light as the intrinsic light, and
the two or more kinds of phosphors are disposed in a lateral direction in such a state as not to vertically overlap with each other, to suppress interaction between the phosphors.

2. The light-emitting apparatus according to claim 1, wherein a phosphor layer, which is configured of the phosphors constituting the phosphor separate-type structure, has a thickness of not larger than 500 μm.

3. The light-emitting apparatus according to claim 2, wherein
the light-emitting apparatus is configured such that light is emitted by the semiconductor light-emitting element for emitting blue light, purple light or ultraviolet light and the phosphor layer formed on a light extraction surface of the semiconductor light-emitting element, and
the phosphor layer is configured by being divided into a plurality of regions vertically to a layer surface so that any one phosphor of the blue phosphor, the green phosphor, the red phosphor and the yellow phosphor is allocated to each of the divided regions and so that a percentage of a gross area of the red phosphor to a total area of the phosphor layer becomes the largest, to constitute the specific structure.

4. The light-emitting apparatus according to claim 3, wherein in the light-emitting apparatus, the red phosphor contains a phosphor of a different luminous color for adjusting spectral characteristics.

5. The light-emitting apparatus according to claim 2, wherein
the light-emitting apparatus is configured such that light is emitted by the semiconductor light-emitting element for emitting blue light, purple light or ultraviolet light and the phosphor layer formed on the light extraction surface of the semiconductor light-emitting element, and
an increasing rate of an emission intensity component value S2 of an emission spectrum of the light-emitting apparatus at a wavelength of 530 nm to an emission intensity component value S1 of the emission spectrum at a wavelength of 520 nm, namely (S2−S1)/S1, is a negative value or a positive value and not higher than 6%.

6. The light-emitting apparatus according to claim 3, wherein
the light-emitting apparatus is configured by superimposing and disposing, on the semiconductor light-emitting element which emits blue light, purple light or ultraviolet light, has two opposing principal surfaces, and takes the one principal surface as a light extraction surface and the other principal surface as an electrode formation surface, a phosphor-containing film piece which has two opposing principal surfaces equivalent to or larger than the light extraction surface and takes the one principal surface as a light entrance surface and the other principal surface as a light exit surface, such that the light extraction surface and the light entrance surface are opposed to each other, and
the phosphor-containing film piece is configured by being divided into a plurality of regions vertically to the principal surface so that any one phosphor of the blue phosphor, the green phosphor, the red phosphor and the yellow phosphor is allocated to each of the divided regions, to constitute the specific structure.

7. The light-emitting apparatus according to claim 6, wherein
the number of regions of the phosphor-containing film piece is set to one, and
any one kind of the blue phosphor, the green phosphor, the red phosphor and the yellow phosphor is allocated to the region.

8. An LED illumination apparatus, wherein interaction between phosphors is suppressed by use of the light-emitting apparatus according to claim 1.

9. A method for manufacturing a phosphor-containing film piece used in the light-emitting apparatus according to claim 6, the method comprising:
a step 1 of mixing a resin and first phosphor powder of any of a blue phosphor, a green phosphor, a red phosphor and a yellow phosphor to make a paste, applying the paste in a film form onto a heat resistant plastic sheet, and curing the paste to form a first phosphor-containing film piece;
a step 2 of removing the first phosphor-containing film from a portion region for the first phosphor-containing film piece (a portion corresponding to the divided region); and
a step 3 of applying a paste, obtained by mixing a resin and second phosphor powder of any of the blue phosphor, the green phosphor, the red phosphor and the yellow phosphor and making the mixture into a paste form, into the portion region and curing the paste to form a second phosphor-containing film divided region.

10. The method for manufacturing a phosphor-containing film piece used in the light-emitting apparatus according to claim 9, wherein steps corresponding to the step 2 and the step 3 are repeated a plurality of times, to form a plurality of phosphor-containing film divided regions.
